(19) United States
(12) Patent Application Publication
(10) Pub. No.: US 2016/0351751 A1
(43) Pub. Date: Dec. 1, 2016

(54) SEMICONDUCTOR LIGHT EMITTING STRUCTURE AND MANUFACTURING METHOD THEREOF

(71) Applicant: Lextar Electronics Corporation, Hsinchu (TW)

(72) Inventors: Cheng-Hung Chen, Hsinchu City (TW); Chao-Hsien Lin, New Taipei City (TW)

(21) Appl. No.: 14/886,182

(22) Filed: Oct. 19, 2015

(30) Foreign Application Priority Data
May 25, 2015 (TW) 104116626

(51) Int. Cl. H01L 33/40; H01L 33/38

(52) U.S. Cl. CPC H01L 33/405; H01L 33/38; H01L 2933/0016; H01L 2933/0033

(57) ABSTRACT

A semiconductor light emitting structure and a manufacturing method thereof are provided. The semiconductor light emitting structure includes a substrate, an epitaxial layer and a stepped electrode. The substrate has a first surface and a second surface opposite to the first surface. The epitaxial layer is formed by a first semiconductor layer, an active layer and a second semiconductor layer which are stacked on the first surface in sequence. The stepped electrode is formed within the epitaxial layer, and includes a main body portion, a step level and a reflection electrode portion extended towards the first surface from the step level. The main body portion at least passes through the second semiconductor layer and the active layer. The reflection electrode portion is extended into the first semiconductor layer from the main body portion.

This application claims the benefit of Taiwan application Ser. No. 104116626, filed May 25, 2015, the subject matter of which is incorporated herein by reference.

### BACKGROUND OF THE INVENTION

1. Field of the Invention

The invention relates in general to a light emitting structure, and more particularly to a semiconductor light emitting structure with stepped electrode and a manufacturing method thereof.

2. Description of the Related Art

Light-emitting diode (LED) emits a light by converting an electric energy into an optical energy. After a current is applied to the LED, the current is diffused and infused to an epitaxial layer of the LED, such that electrons and holes are combined and release energy in the form of a light. The LED has the advantages of long lifespan, power saving and small volume. Along with the development of multicolor domains and high brightness in recent years, the LED has been widely used in the field of white light illumination to replace conventional fluorescent tube.

The LED normally uses sapphire as a base for the growth of the epitaxial layer. However, the sapphire base has a high refractive index, and the light with an angle greater than the total reflection angle may easily be reflected back to the epitaxial layer by the sapphire base. Therefore, a part of the light will be absorbed and cannot be completely extracted, making the epitaxial layer have an unsatisfactory efficiency of light extraction.

### SUMMARY OF THE INVENTION

The invention is directed to a semiconductor light emitting structure and a manufacturing method thereof, in which a stepped electrode is formed within the epitaxial layer to effectively reduce the likelihood of the light being reflected and absorbed and increase the efficiency of light extraction for the epitaxial layer.

The invention is directed to a semiconductor light emitting structure and a manufacturing method thereof, in which a stepped electrode is formed within the epitaxial layer for increasing the contact area between the electrode and the semiconductor layer.

According to one embodiment of the present invention, a semiconductor light emitting structure is provided. The semiconductor light emitting structure includes a substrate, an epitaxial layer and a stepped electrode. The substrate has a first surface and a second surface opposite to the first surface. The epitaxial layer is formed by a first semiconductor layer, an active layer and a second semiconductor layer which are stacked on the first surface in sequence. The stepped electrode is formed within the epitaxial layer, and includes a main body portion, a step level and a reflection electrode portion extended towards the first surface from the step level. The main body portion at least passes through the second semiconductor layer and the active layer. The reflection electrode portion is extended into the first semiconductor layer from the main body portion.

According to another embodiment of the present invention, a method for manufacturing semiconductor light emitting structure is provided. The method includes following steps. A substrate having a first surface and a second surface opposite to the first surface is provided. An epitaxial layer is formed by stacking a first semiconductor layer, an active layer and a second semiconductor layer on the first surface in sequence. The epitaxial layer is etched to form a recess. A stepped electrode is formed inside the recess of the epitaxial layer. The stepped electrode includes a main body portion, a step level and a reflection electrode portion extended towards the first surface from the step level. The main body portion passes through the second semiconductor layer and the active layer. The reflection electrode portion is extended into the first semiconductor layer from the main body portion.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a cross-sectional view of a semiconductor flip-chip package structure according to an embodiment of the invention.

FIG. 2A shows a schematic diagram of a semiconductor light emitting structure according to an embodiment of the invention.

FIG. 2B shows a schematic diagram of a semiconductor light emitting structure according to an embodiment of the invention.

FIGS. 3A-3D show a flowchart of a method for manufacturing a semiconductor light emitting structure according to an embodiment of the invention.

FIG. 4 shows a relationship of the brightness of light output of the light emitting unit vs. the area percentage of N-type electrode.

### DETAILED DESCRIPTION OF THE INVENTION

A number of embodiments are disclosed below for elaborating the invention. However, the embodiments of the invention are for detailed descriptions only, not for limiting the scope of protection of the invention.

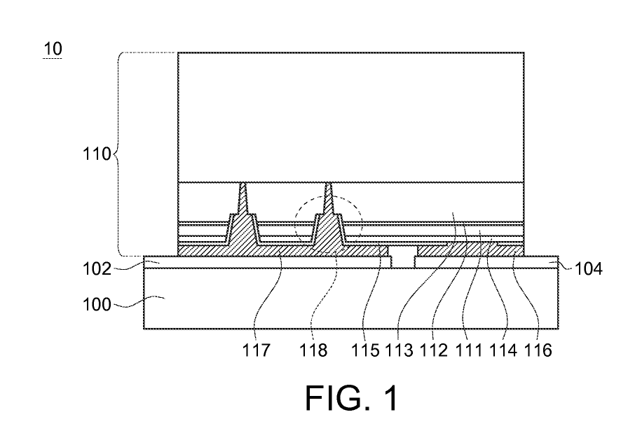

Referring to FIG. 1, a cross-sectional view of a semiconductor flip-chip package structure 10 according to an embodiment is shown.

In one embodiment, the semiconductor flip-chip package structure 10 includes a carrier 100 and a light emitting unit 110. The light emitting unit 110 is disposed on the carrier 100, and the light emitting unit 110 has a P-type electrode 116 and an N-type electrode 117. The P-type electrode 116 is electrically connected to the positive electrode 104 of the carrier 100, and the N-type electrode 117 is electrically connected to the negative electrode 102 of the carrier 100 for transmitting and diffusing a current to the light emitting unit 110, such that electrons and holes in the light emitting unit 110 being driven by a voltage are combined to emit a light.

The light emitting unit 110, which can be a gallium nitride LED structure, includes a P-type semiconductor layer 111, a multiple quantum well layer 112 and an N-type semiconductor layer 113. Of the semiconductors, those having a larger ratio of holes carrying positive electricity are referred as P type semiconductors, and those having a larger ratio of electrons carrying negative electricity are referred as N type semiconductors. A PN junction is formed within the multiple quantum well layer 112 at a junction between the P-type semiconductor and the N-type semiconductor. When electrons and holes are combined at the PN junction, energy is released in the form of a light. The multiple quantum well layer 112 increases the efficiency of converting an electric energy of the LED into an optical energy.

In one embodiment, the light emitting unit 110 can be disposed on the circuit carrier 100 with superior thermal conductivity, such as a metal-cored substrate, a ceramic substrate or a silicone substrate, such that the semiconductor flip-chip package structure 10 can have superior efficiency of dissipating the heat and emitting the light.

Additionally, the semiconductor flip-chip package structure 10 further includes a reflective layer 114 disposed on the P-type semiconductor layer 111. The reflective layer 114 can be formed of indium tin oxide (ITO), aluminum zinc oxide (AZO), zinc oxide (ZnO), graphene, aluminum (Al), silver (Ag), a nickel (Ni), cobalt (Co), palladium (Pd), platinum (Pt), gold (Au), zinc (Zn), tin (Sn), antimony (Sb), lead (Pb), copper (Cu), copper-silver (Cu/Ag) or an alloy thereof. The reflective layer 114 is used for reflecting the light and increasing the efficiency of light extraction. Besides, the reflective layer 114 can also be used as an Ohm contact layer interposed between the P-type semiconductor layer 111 and the P-type electrode 116.

Moreover, the semiconductor flip-chip package structure 10 further includes an insulating layer 115 covering the reflective layer 114 and a side wall of the N-type electrode 117 to avoid the N-type electrode 117, which passes through the reflective layer 114, the P-type semiconductor layer 111 and the multiple quantum well layer 112, short-circuiting with the P-type electrode 116. The present embodiment only illustrates two protrusions 118 of the N-type electrode 117, which pass through the reflective layer 114, the P-type semiconductor layer 111 and the multiple quantum well layer 112 and are electrically connected to the N-type semiconductor layer 113. The quantity of protrusions 118 may range between 10˜20. With the disposition of 10˜20 protrusions 118, the contact area between the N-type electrode 117 and the N-type semiconductor layer 113 can be relatively increased, and the electrons can be uniformly diffused to each region of the N-type semiconductor layer 113.

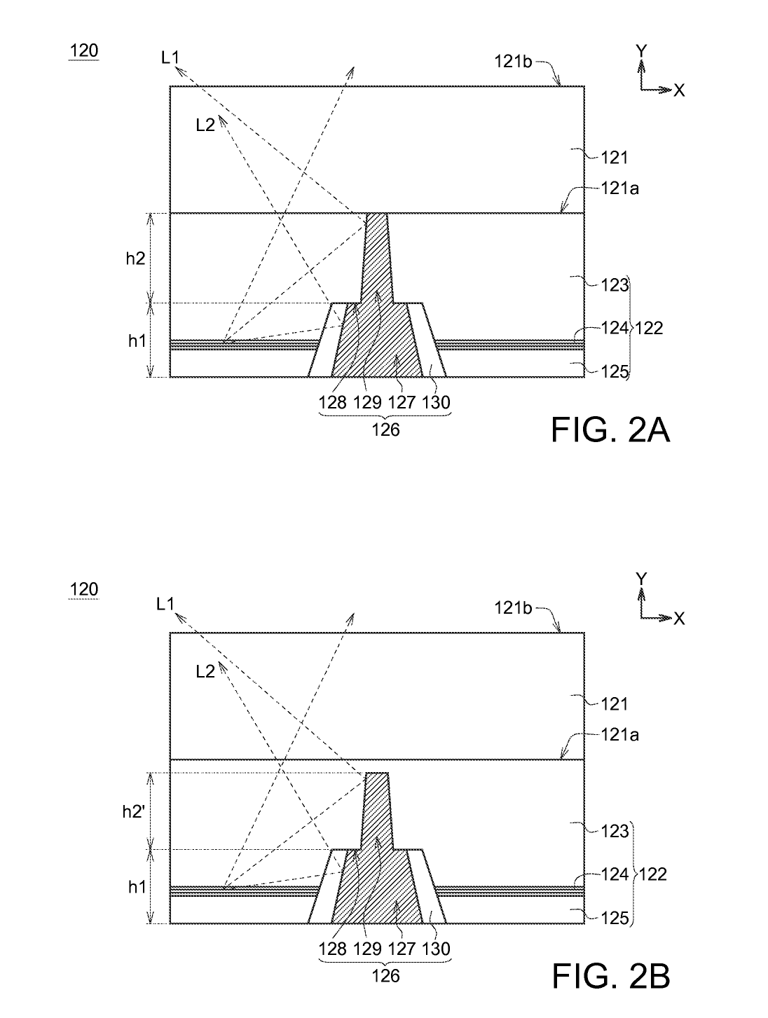

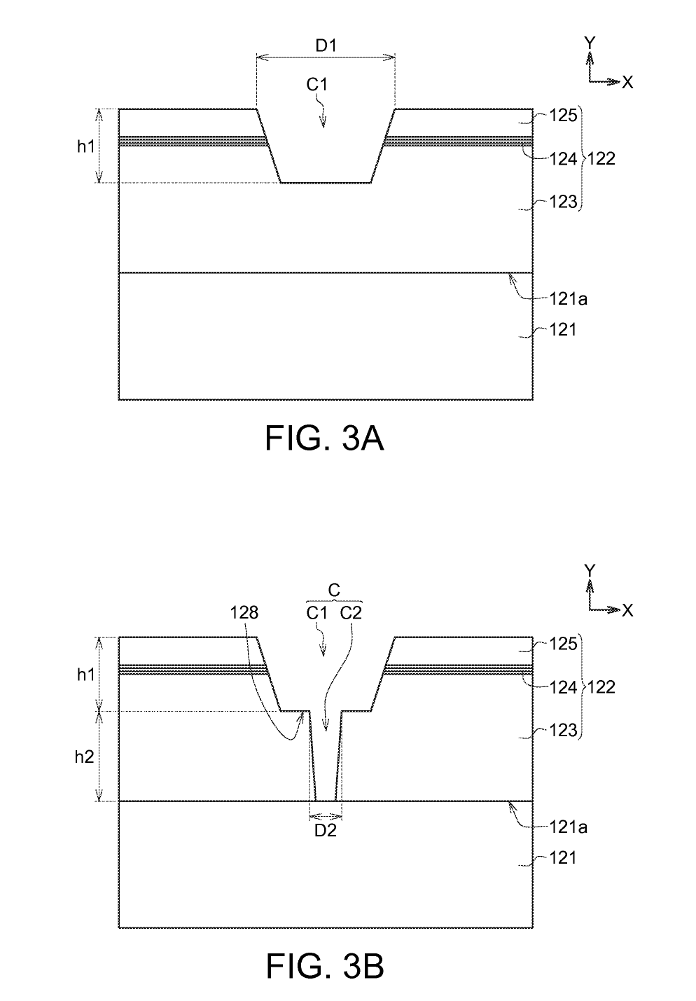

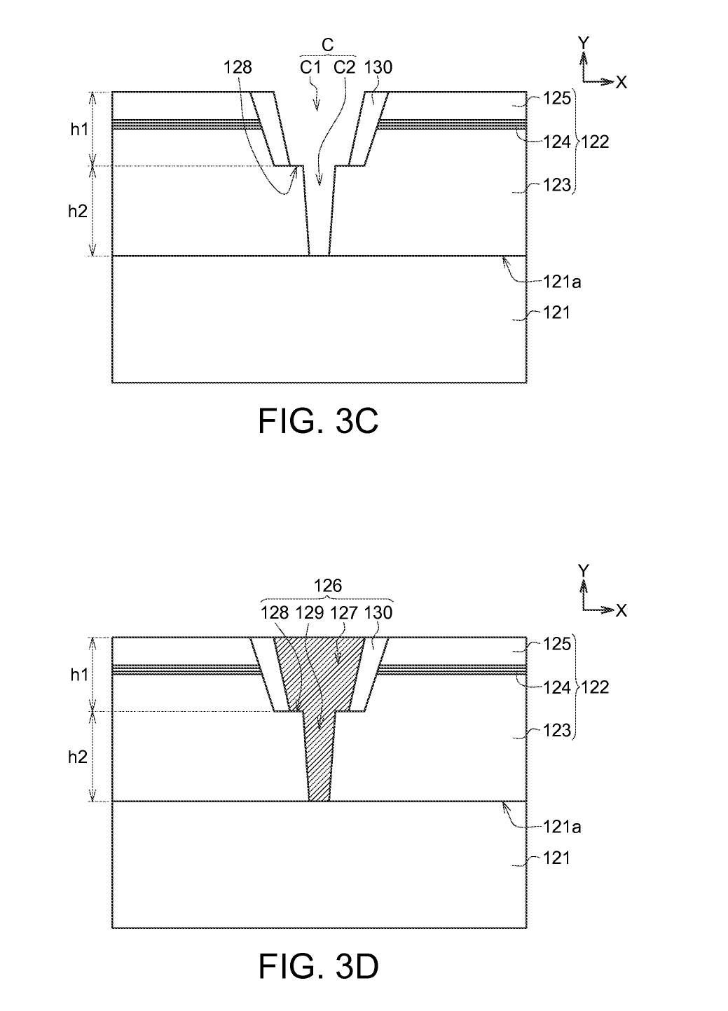

A semiconductor light emitting structure 120 of the light emitting unit 110 and a manufacturing method thereof are disclosed below. Refer to FIGS. 2A, 2B and 3A-3D. FIG. 2A shows a schematic diagram of a semiconductor light emitting structure 120 according to an embodiment of the invention. FIG. 2B shows a schematic diagram of a semiconductor light emitting structure 120 according to another embodiment of the invention. FIGS. 3A-3D show a flowchart of a method for manufacturing a semiconductor light emitting structure 120 according to an embodiment of the invention.

The semiconductor light emitting structure 120 includes a substrate 121, an epitaxial layer 122 and a stepped electrode 126. The substrate 121 can be made of a non-conductive transparent insulating material, such as glass, plastics or sapphire. Preferably, the substrate 121 is a sapphire substrate, a silicon carbide substrate or a silicone substrate, but the invention is not limited thereto. The substrate 121 has a first surface 121a and a second surface 121b disposed in parallel and opposite to each other. The epitaxial layer 122 is formed by a first semiconductor layer 123, an active layer 124 and a second semiconductor layer 125, which are stacked on the first surface 121a in sequence. The first semiconductor layer 123, the active layer 124 and the second semiconductor layer 125 are formed of a material selected from a group composed of gallium nitride (GaN), indium gallium nitride (InGaN), aluminum gallium nitride (AIGaN) or indium gallium aluminum nitride (AlInGaN) or a combination thereof. The first semiconductor layer 123 can be an N-type semiconductor layer. The second semiconductor layer 125 can be a P-type semiconductor layer. The active layer 124 can be a multiple quantum well layer for increasing the efficiency of converting an electric energy into an optical energy of the LED.

The stepped electrode 126 is formed within the epitaxial layer 122, and includes a main body portion 127, a step level 128 and a reflection electrode portion 129 extended towards the first surface 121a of the substrate 121 from the step level 128.

Refer to FIG. 2A. In the vertical arrangement direction Y, the main body portion 127 passes through the second semiconductor layer 125, the active layer 124 and a part of the first semiconductor layer 123. The reflection electrode portion 129, extended from the main body portion 127, passes through the other part of the first semiconductor layer 123 to reach the first surface 121a. The main body portion 127 has a first depth size h1, and the reflection electrode portion 129 has a second depth size h2. The sum of the first depth size h1 and the second depth size h2 is approximately equivalent to the actual thickness of the epitaxial layer 122, that is, about 6˜8 μm.

In an embodiment, the main body portion 127 and the reflection electrode portion 129 are formed inside a recess C of the epitaxial layer 122 by way of electroplating or chemical vapor deposition. The recess C includes a first indent C1 and a second indent C2. The manufacturing method related to the first indent C1 and the second indent C2 is disclosed with reference to FIGS. 3A and 3B.

Referring to FIG. 3A, etching the epitaxial layer 122 to form a first indent C1. The method for etching the epitaxial layer 122 includes dry etching or wet etching such as plasma etching or photolithography which defines the width and depth of the first indent C1. The first indent C1 passes through the second semiconductor layer 125, the active layer 124 and a part of the first semiconductor layer 123, and has a width size D1 in the horizontal direction X. Referring to FIG. 3B, the first semiconductor layer 123 is continuously etched from the step level 128 to form a second indent C2 having a width size D2 in the horizontal direction X. The width size D1 of the first indent C1 is greater than the width size D2 of the second indent C2, and the step level 128 is disposed between the first indent C1 and the second indent C2 to form a stepped structure.

In the present embodiment, the depth (the second depth size h2) of the second indent C2 is greater than or equal to the depth (the first depth size h1) of the first indent C1. In general, the depth size h1 of the first indent C1 is greater than the sum of the thickness of the active layer 124 and the second semiconductor layer 125, such that the step level 128 is disposed within the first semiconductor layer 123. The depth size h1 of the first indent C1 is between 1˜1.1 μm, but the invention is not limited thereto. Furthermore, the depth size h2 of the second indent C2 is related to the thickness of the first semiconductor layer 123. For example, the depth size h2 of the second indent C2 is positively correlated with the thickness of the first semiconductor layer 123. When the thickness of the first semiconductor layer 123 is reduced, the depth size h2 of the second indent C2 will be reduced accordingly. The thickness of the first semiconductor layer 123 is between 1˜7 μm. Refer to FIG.

3B. The depth of the second indent C2 can be extended to the first surface 121a of the substrate 121, such that the depth size h2 of the second indent C2 can reach a maximum.

As indicated in FIG. 2A, the stepped electrode 126 includes an insulating layer 130, which surrounds the main body portion 127 and covers a part of the step level 128. The main body portion 127 can be separated from or electrically isolated from the active layer 124 and the second semiconductor layer 125 through the insulating layer 130. Refer to FIG. 3C. The insulating layer 130 is merely formed inside the first indent C1. A part of the step level 128 and the second indent C2 are not covered by the insulating layer 130. As indicated in FIG. 3D, the contact area between the first semiconductor layer 123 and the stepped electrode 126, which is subsequently electroplated or deposited, can be increased. The contact area that is actually increased is the contact area between the reflection electrode portion 129 and the first semiconductor layer 123.

Refer to FIGS. 3C and 3D. The main body portion 127 is disposed inside the first indent C1, and the reflection electrode portion 129 is disposed inside the second indent C2. The depth of the second indent C2 can be extended to the first surface 121a of the substrate 121, such that the reflection electrode portion 129 is extended to the first surface 121a of the substrate 121 from the main body portion 127.

In an embodiment indicated in FIG. 2B, the reflection electrode portion 129 is extended into the first semiconductor layer 123 from the main body portion 127 but does not contact the first surface 121a of the substrate 121. That is, in the vertical arrangement direction Y, the main body portion 127 has a first depth size h1, the reflection electrode portion 129 has a second depth size h2′, and the sum of the thickness of the first depth size h1 and the second depth size h2′ is smaller than the actual thickness of the epitaxial layer 122.

Both the main body portion 127 and the reflection electrode portion 129 can be used for reflecting the light to increase the likelihood of the reflected light being outputted towards the disposition direction of the substrate 121. For example, when the lights L1 and L2 are respectively blocked by the reflection electrode portion 129 and the main body portion 127, the optical paths of the lights L1 and L2 are changed lest the incident angles of the lights L1 and L2 with respect to the substrate 121 might be greater than a full reflection angle and be reflected to the epitaxial layer 122 by the substrate 121. Therefore, the stepped electrode 126 formed in the epitaxial layer 122 can effectively reduce the likelihood of the light being reflected and absorbed, hence increasing the efficiency of light extraction for the epitaxial layer 122. Moreover, since the stepped electrode 126 additionally has a contact area between the reflection electrode portion 129 and the first semiconductor layer 123, electrons can be uniformly diffused over each region of the first semiconductor layer 123, such that the voltage will be reduced and the current will not be overcrowded in the light emitting unit.

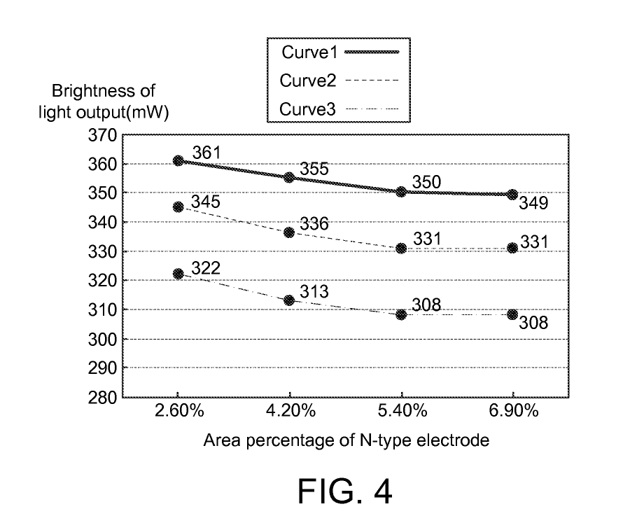

Referring to FIG. 4, a relationship of the brightness of light output of the light emitting unit 110 vs. the area percentage of N-type electrode 117 of FIG. 1 is shown. Curve 1 denotes the brightness of the light emitting unit 110 without the reflective layer 114, wherein the brightness is between 308˜322 mW. Curve 2 denotes the brightness of the light emitting unit 110 with the reflective layer 114, wherein the brightness is between 331˜345 mW.

In comparison to the brightness of light output as indicated in curve 1, the brightness of light output as indicated in curve 2 is increased by about 7%. Curve 3 denotes the brightness of the light emitting unit 110 with the reflective layer 114 and the stepped electrode 126 (h1+h2=2.8 μm) whose height is increased by h2 μm, wherein the brightness is between 349˜361 mW. In comparison to the brightness of light output as indicated in curve 2, the brightness of light output as indicated in curve 3 is again increased by about 4.55˜5.5%. Thus, the disposition of the stepped electrode 126 increases the efficiency of light extraction for the light emitting unit 110.

The above embodiments of the invention disclose a semiconductor light emitting structure with stepped electrodes and a manufacturing method thereof. The semiconductor light emitting structure with stepped electrodes is capable of increasing efficiency of light extraction and contact area. The formation of the stepped electrode is as follows. An epitaxial layer is formed by stacking a first semiconductor layer, an active layer and a second semiconductor layer on the first surface of the substrate in sequence. The epitaxial layer is etched to form a recess. Then, a stepped electrode is formed in a recess of the epitaxial layer. The stepped electrode includes a main body portion, a step level, and a reflection electrode portion extended towards the first surface from the step level. The main body portion passes through the second semiconductor layer and the active layer. The reflection electrode portion is extended into the first semiconductor layer from the main body portion. Besides, the semiconductor light emitting structure manufactured according to the above steps can be disposed on a carrier. The substrate is disposed in a flip-chip manner with the first surface facing towards the carrier, such that the semiconductor light emitting structure and the carrier are combined to form a semiconductor flip-chip package structure.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A semiconductor light emitting structure, comprising:
a substrate having a first surface and a second surface opposite to the first surface;
an epitaxial layer formed by a first semiconductor layer, an active layer and a second semiconductor layer which are stacked on the first surface in sequence;
a stepped electrode formed within the epitaxial layer and comprising a main body portion, a step level and a reflection electrode portion extended towards the first surface from the step level, wherein the main body portion at least passes through the second semiconductor layer and the active layer, and the reflection electrode portion is extended into the first semiconductor layer from the main body portion, wherein the main body portion is insulated from the active layer and the second semiconductor layer, and sidewalls of the reflection electrode portion is in direct contact with the first semiconductor layer.

2. The semiconductor light emitting structure according to claim 1, wherein the epitaxial layer has a recess extended towards the substrate from the second semiconductor layer and comprising a first indent and a second indent in sequence, the step level is formed between the first indent and the second indent, the main body portion is disposed inside the first indent, and the reflection electrode portion is disposed inside the second indent.

3. The semiconductor light emitting structure according to claim 2, wherein the first indent passes through the second semiconductor layer, the active layer and a part of the first semiconductor layer, the step level is disposed within the first semiconductor layer, and the second indent passes through the other part of the first semiconductor layer from the step level.

4. The semiconductor light emitting structure according to claim 3, wherein a width size of the first indent is greater than a width size of the second indent to form a stepped structure.

5. The semiconductor light emitting structure according to claim 3, wherein a depth size of the second indent is greater than a depth size of the first indent.

6. The semiconductor light emitting structure according to claim 5, wherein the depth of the second indent is extended to the first surface, such that the reflection electrode portion in the second indent contacts the first surface.

7. The semiconductor light emitting structure according to claim 2, wherein the stepped electrode comprises an insulating layer which is formed inside the first indent and surrounds the main body portion electrically, and the main body portion is insulated from the active layer and the second semiconductor layer through the insulating layer.

8. The semiconductor light emitting structure according to claim 1, wherein the semiconductor light emitting structure is disposed on a carrier, and the substrate is disposed in a flip-chip manner with the first surface facing toward the carrier, such that the semiconductor light emitting structure and the carrier are combined to form a semiconductor flip-chip package structure.

9. A method for manufacturing a semiconductor light emitting structure, comprising:
providing a substrate having a first surface and a second surface opposite to the first surface;
forming an epitaxial layer by stacking a first semiconductor layer, an active layer and a second semiconductor layer on the first surface in sequence;
etching the epitaxial layer to form a recess; and
forming a stepped electrode, which is inside the recess of the epitaxial layer and comprises a main body portion, a step level and a reflection electrode portion extended towards the first surface form the step level, wherein the main body portion passes through the second semiconductor layer and the active layer, and the reflection electrode portion is extended into the first semiconductor layer from the main body portion, wherein the main body portion is insulated from the active layer and the second semiconductor layer, and sidewalls of the reflection electrode portion is in direct contact with the first semiconductor layer.

10. The method for manufacturing a semiconductor light emitting structure according to claim 9, wherein the recess is extended towards the substrate from the second semiconductor layer and comprises a first indent and a second indent in sequence, the step level is formed between the first indent and the second indent, the main body portion is disposed inside the first indent, and the reflection electrode portion is disposed inside the second indent.

11. The method for manufacturing a semiconductor light emitting structure according to claim 10, wherein the step of forming the first indent comprises etching the epitaxial layer, such that the first indent passes through the second semiconductor layer, the active layer and a part of the first semiconductor layer, and the step level is disposed within the first semiconductor layer; the formation of the second indent comprises continuously etching the first semiconductor layer from the step level, such that the second indent passes through the other part of the first semiconductor layer.

12. The method for manufacturing a semiconductor light emitting structure according to claim 11, wherein a width size of the first indent is greater than a width size of the second indent to form a stepped structure.

13. The method for manufacturing a semiconductor light emitting structure according to claim 11, wherein a depth size of the second indent is greater than a depth size of the first indent.

14. The method for manufacturing a semiconductor light emitting structure according to claim 13, wherein the depth of the second indent is extended to the first surface, such that the reflection electrode portion in the second indent contacts the first surface.

15. The method for manufacturing a semiconductor light emitting structure according to claim 10, wherein the step of forming the stepped electrode comprises forming an insulating layer which is inside the first indent and surrounds the main body portion, and the main body portion is electrically insulated from the active layer and the second semiconductor layer through the insulating layer.

16. The method for manufacturing a semiconductor light emitting structure according to claim 9, wherein the semiconductor light emitting structure is disposed on a carrier, and the substrate is disposed in a flip-chip manner with the first surface facing towards the carrier, such that the semiconductor light emitting structure and the carrier are combined to form a semiconductor flip-chip package structure.
